(19) United States
(12) Patent Application Publication
(10) Pub. No.: US 2010/0183853 A1
(43) Pub. Date: Jul. 22, 2010

(54) STRIPPING AGENT FOR RESIST FILM ON/ABOVE CONDUCTIVE POLYMER, METHOD FOR STRIPPING RESIST FILM, AND SUBSTRATE HAVING PATTERNED CONDUCTIVE POLYMER

(76) Inventor: Takashi Ihara, Aichi (JP)

Correspondence Address: KRATZ, QUINTOS & HANSON, LLP, 1420 K Street, N.W., 4th Floor, WASHINGTON, DC, 20005, US

(21) Appl. No.: 12/663,142

(22) PCT Filed: May 27, 2008
(86) PCT No.: PCT/JP2008/059706

§ 371 Date: Dec. 4, 2009

(30) Foreign Application Priority Data
Jun. 12, 2007 (JP) 2007-155529
Dec. 10, 2007 (JP) 2007-317796

(51) Int. Cl. G03F 7/42; B08B 3/00; B32B 3/10

(52) U.S. Cl. 428/195.1; 510/176; 134/26

(57) ABSTRACT

The object of the present invention is to provide a stripping agent that not only has excellent stripping properties but also does not adversely affect a conductive polymer when a resist film is stripped from the conductive polymer, and a method for stripping a resist film on/above a conductive polymer. Furthermore, the object is to provide a substrate having a patterned conductive polymer that has good conductivity.

The stripping agent for a resist film on/above a conductive polymer of the present invention includes at least one organic solvent selected from the group consisting of an aprotic organic solvent (a) that is selected from the group consisting of a dialkylsulfone, a dialkyl sulfoxide, an alkylene carbonate, and an alkyrolactone and does not have a nitrogen atom and an organic solvent (b) that has a nitrogen atom in the chemical structure and is one other than a primary amine compound, a secondary amine compound, and an organic quaternary ammonium salt.

### TECHNICAL FIELD

The present invention relates to a stripping agent for a resist film on/above a conductive polymer, a resist film stripping method, and a substrate having a patterned conductive polymer.

### BACKGROUND ART

In recent years, as a transparent conductive film one containing ITO (indium tin oxide) as a component has been used, but since indium is a rare element, research into conductive polymers as alternatives has been carried out.

These conductive polymers not only have excellent conductivity, optical transmission, and luminescence, but also have excellent film forming properties, thin film properties, and flexibility, and development of the application thereof to electrolytic capacitors, antistatic films, polymer EL, solar cells, and transparent conductive films has been carried out.

For example, in the case of electrolytic capacitors, the use of a conductive polymer having higher conductivity than that of an electrolyte enables an electrolytic capacitor to be formed that is chemically and physically stable and has excellent heat resistance and good frequency characteristics.

Furthermore, since static electricity can be prevented while maintaining transparency by forming a thin film of a conductive polymer on the surface of a polymer film, it can be used as an antistatic film or an antistatic container having good ease of use.

When a conductive polymer is used as an alternative to ITO, it is necessary to employ a patterning method that is practical, useful, and highly productive, and various types of patterning methods have been examined.

For example, patterning by an inkjet printing method is known (Patent Document 1).

On the other hand, a method in which a conductive polymer formed as a film is coated with a photoresist, a pattern is formed in the resist film using photolithography, and the conductive polymer as a lower layer is then etched using an etching agent via the resist film as a mask material has the advantage that a pattern having a high aspect ratio can be formed with good precision.

A method for patterning a conductive polymer by etching is disclosed in, for example, Patent Document 2.

There are many cases in the application of conductive polymers in which patterning is carried out. For example, a lead-out line when it is used as an electrode of a touch panel or a polymer EL display can be cited. When carrying out patterning by photolithography, it is essential to use a stripping liquid for a photoresist and, for example, a resist stripping liquid composition comprising an aprotic polar organic solvent, an organic amine or an organic quaternary ammonium salt, a polyalkylene glycol, and water, and a photoresist stripping liquid comprising a polyhydric alcohol, an alkanolamine, glycol ether, and water have been disclosed (Patent Documents 3 and 4).

Furthermore, with regard to patterning of a conductive polymer, a method for forming a conductive pattern comprising a step of forming in order on a support a conductive polymer-containing layer and a photosensitive resin layer, a step of exposing the photosensitive resin layer, and a step of removing the conductive polymer-containing layer corresponding to an exposed part or a non-exposed part of the photosensitive resin layer together with the exposed part or the non-exposed part has been disclosed (Patent Document 5).

Moreover, it is generally necessary to heat a stripping liquid for use in a stripping treatment of a resist film in order to reduce the stripping time and prevent incomplete stripping, and the treatment is often carried out at a temperature higher than 60° C. Specifically, an example in which stripping is carried out at 70° C. using a stripping liquid having high anticorrosive properties has been shown (Patent Document 6).

[Patent Document 1] JP-A-2005-109435 (JP-A denotes a Japanese unexamined patent application publication)

### [Patent Document 2] JP-A-5-335718

### [Patent Document 3] JP-A-2004-177740

### [Patent Document 4] JP-A-2007-114519

### [Patent Document 5] JP-A-2003-346575

### [Patent Document 6] JP-A-2001-356495

### DISCLOSURE OF INVENTION

### Problems to be Solved by the Invention

The method described in Patent Document 1 is a simple method with good precision since patterning is carried out by printing, but there is the defect that it is difficult to make an ink using a conductive polymer.

The method described in Patent Document 2 requires stripping of a resist film as an upper layer after a conductive polymer is etched.

On the other hand, when the stripping liquid described in Patent Documents 3 and 4 is used for stripping a resist film on a conductive polymer, since the conductive polymer contains a conductive group such as, for example, a thiophene group in the molecule, it might react with ammonia or a piperazine, which are basic, contained in the stripping liquid or it might be oxidized, thus giving rise to the problems that the conductivity decreases and penetration into the conductive polymer occurs, thereby degrading adhesion between a substrate and the conductive polymer.

Furthermore, in the method for forming a conductive pattern described in Patent Document 5, when a photosensitive resin layer is removed after patterning a conductive polymer layer, use of an ether-based or ketone-based solvent is disclosed. The present inventors have found that there are the problems that these solvents are difficult to handle, a conductive polymer layer is also stripped, etc.

Moreover, in the method described in Patent Document 6 a phenomenon has been observed in which the conductivity of the conductive polymer is degraded and the surface resistivity increases by at least 50%.

That is, when the surface resistivity of a conductive polymer film is compared with that of an ITO film, in the case of a thin film in which the film transmittance is 80% or greater, the surface resistivity of ITO is no greater than 100 Ω/square, whereas the surface resistivity of the conductive polymer is 100 to 10,000 Ω/square, and in order to replace the ITO by the conductive polymer, any increase in surface resistivity due to the influence of chemical agents must be minimized.

Furthermore, even when transmittance is not required, degradation of the conductivity should be prevented, but countermeasures involving increasing the thickness result in a narrowing of the range of application thereof.

It is an object of the present invention to provide a stripping agent that not only has excellent stripping properties but also does not adversely affect a conductive polymer when a resist film is stripped from the conductive polymer, and a method for stripping a resist film on/above a conductive polymer. Furthermore, it is another object of the present invention to provide a substrate having a patterned conductive polymer that has good conductivity.

### Means for Solving the Problems

As a result of an intensive investigation by the present inventors in order to solve the problems of the above-mentioned conventional techniques, it has been found that the above-mentioned object can be attained by means described in [1], [10], and [17] below, and the present invention has thus been accomplished. They are described together with [2] to [9] and [11] to [16], which are preferred embodiments.

[1] A stripping agent for a resist film on/above a conductive polymer, comprising at least one organic solvent selected from the group consisting of an aprotic organic solvent (a) that is selected from the group consisting of a dialkylsulfone, a dialkyl sulfoxide, an alkylene carbonate, and an alkyrolactone and does not have a nitrogen atom and an organic solvent (b) that has a nitrogen atom in the chemical structure and is one other than a primary amine compound, a secondary amine compound, and an organic quaternary ammonium salt,
[2] the stripping agent for a resist film on/above a conductive polymer according to [1] above, wherein the aprotic organic solvent (a) comprises at least one aprotic organic solvent selected from the group consisting of a dialkyl sulfoxide, an alkylene carbonate, and an alkyrolactone,
[3] the stripping agent for a resist film on/above a conductive polymer according to [1] or [2] above, wherein the aprotic organic solvent (a) comprises at least one aprotic organic solvent selected from the group consisting of dimethyl sulfoxide, ethylene carbonate, propylene carbonate, and γ-butyrolactone,
[4] the stripping agent for a resist film on/above a conductive polymer according to any one of [1] to [3] above, wherein it comprises the aprotic organic solvent (a) and the organic solvent (b),
[5] the stripping agent for a resist film on/above a conductive polymer according to [4] above, wherein the ratio of the aprotic organic solvent (a) to the organic solvent (b) is (a)/(b)=99/1 to 10/90 (ratio by weight),
[6] the stripping agent for a resist film on/above a conductive polymer according to any one of [1] to [5] above, wherein the organic solvent (b) comprises at least one organic solvent selected from the group consisting of an N-alkylpyrrolidone and a dialkylcarboamide,
[7] the stripping agent for a resist film on/above a conductive polymer according to any one of [1] to [6] above, wherein the organic solvent (b) comprises at least one organic solvent selected from the group consisting of N-methylpyrrolidone, dimethylformamide, and dimethylacetamide,
[8] the stripping agent for a resist film on/above a conductive polymer according to any one of [1] to [7] above, wherein the conductive polymer is a polyaniline and/or a polythiophene,
[9] the stripping agent for a resist film on/above a conductive polymer according to any one of [1] to [8] above, wherein the conductive polymer is poly(3,4-ethylenedioxythiophene),
[10] a method for stripping a resist film, comprising a step of preparing a substrate having in order on/above the substrate a conductive polymer and a patterned resist film, and a stripping step of stripping the resist film on/above the conductive polymer on the substrate with a stripping agent, the stripping agent being the stripping agent for a resist film on/above a conductive polymer according to any one of [1] to [9] above,
[11] the method for stripping a resist film according to [10] above, wherein it further comprises a washing step of washing with a washing liquid after the stripping step,
[12] the method for stripping a resist film according to [11] above, wherein the stripping step and/or the washing step are carried out at a temperature of 5° C. to 60° C.,
[13] the method for stripping a resist film according to [11] or [12] above, wherein the washing liquid is water, a lower alcohol, or a mixture of water and a lower alcohol,
[14] the method for stripping a resist film according to any one of [10] to [13] above, wherein the conductive polymer is a polyaniline and/or a polythiophene,
[15] the method for stripping a resist film according to any one of [10] to [14] above, wherein the conductive polymer is poly(3,4-ethylenedioxythiophene),
[16] the method for stripping a resist film according to any one of [10] to [15] above, wherein the step of preparing a substrate having in order on/above the substrate a conductive polymer and a patterned resist film comprises a step of forming a conductive polymer film on a substrate, a step of forming a resist film on/above the conductive polymer film, and a step of patternwise exposing the resist film using UV and developing with a developer, and
[17] a substrate having a patterned conductive polymer, a resist being stripped by the method according to any one of [10] to [16] above.

### EFFECTS OF THE INVENTION

In accordance with the present invention, there can be provided a stripping agent that not only has excellent stripping properties but also does not adversely affect a conductive polymer when a resist film is stripped from the conductive polymer, and a method for stripping a resist film on/above a conductive polymer. Furthermore, there can be provided a substrate having a patterned conductive polymer that has good conductivity.

### BRIEF DESCRIPTION OF DRAWINGS

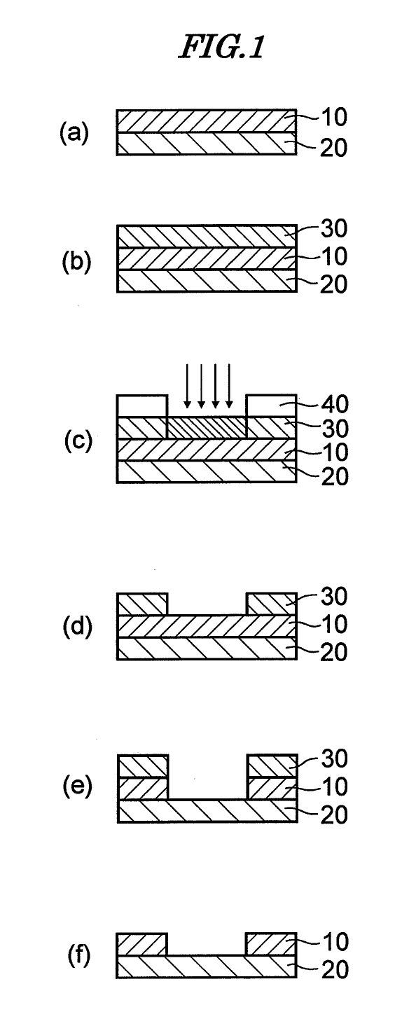

(FIG. 1) A process drawing showing a method for stripping a resist film formed directly on a conductive polymer.

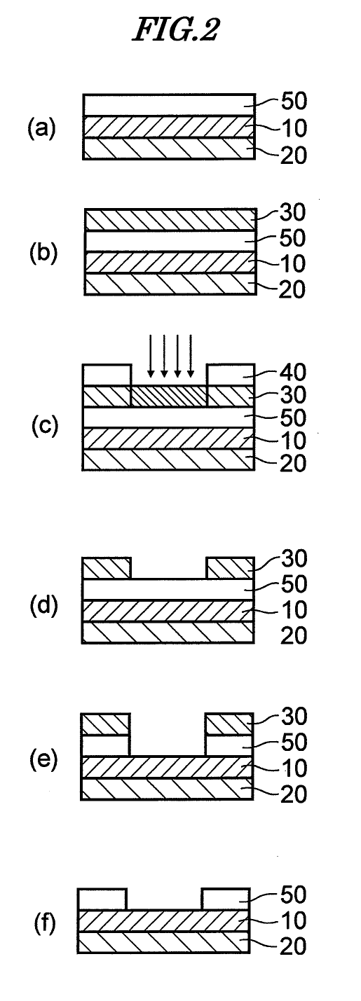

(FIG. 2) A process drawing showing a method for stripping a resist film formed on a conductive polymer via another film.

### EXPLANATION OF REFERENCE NUMERALS AND SYMBOLS

10 Conductive polymer
20 Substrate
30 Resist film
40 Mask pattern
50 Another film

### BEST MODE FOR CARRYING OUT THE INVENTION

### (1) Stripping Agent for Resist Film on/Above Conductive Polymer

The stripping agent for a resist film on/above (on or above) a conductive polymer of the present invention (hereinafter, also simply called a ‘stripping agent’) comprises at least one organic solvent selected from the group consisting of an aprotic organic solvent (a) that is selected from the group consisting of a dialkylsulfone, a dialkyl sulfoxide, an alkylene carbonate, and an alkyrolactone and does not contain a nitrogen atom (in the present invention, also simply called ‘aprotic organic solvent (a)’) and an organic solvent (b) that has a nitrogen atom in the chemical structure and is one other than a primary amine compound, a secondary amine compound, and an organic quaternary ammonium salt (in the present invention, also simply called ‘organic solvent (b)’). That is, the present invention comprises at least one organic solvent selected from the group consisting of the aprotic organic solvent (a) and the organic solvent (b), may employ two or more types of aprotic organic solvents (a) or two or more types of organic solvents (b), or may employ an aprotic organic solvent (a) and an organic solvent (b) in combination.

The aprotic organic solvent (a) and the organic solvent (b) are explained in detail below.

(a) Aprotic Organic Solvent Selected from Group Consisting of Dialkylsulfone, Dialkyl Sulfoxide, Alkylene Carbonate, and Alkyrolactone and not Containing Nitrogen Atom

In the present invention, the aprotic organic solvent means an organic solvent that has very low ability to donate a proton. In contrast thereto, a protic organic solvent means a solvent that produces a proton by self dissociation, examples thereof including water, an alcohol such as methanol or ethanol, a carboxylic acid such as acetic acid, phenol, and liquid ammonia.

In the present invention, the aprotic organic solvent (a) contains an oxygen atom and/or a sulfur atom in the chemical structure and does not contain a nitrogen atom.

Such an aprotic organic solvent (a) is a solvent selected from the group consisting of a dialkyl sulfoxide such as dimethyl sulfoxide or diethyl sulfoxide, a dialkylsulfone such as dimethylsulfone, an alkylene carbonate such as ethylene carbonate or propylene carbonate, and an alkyrolactone such as γ-butyrolactone, δ-valerolactone, and ε-caprolactone. These aprotic organic solvents (a) may be used singly or in a combination of two or more types.

Furthermore, with regard to the dialkyl sulfoxide and the dialkylsulfone, two alkyl groups may be bonded to form a ring; for example, a dialkylsulfone includes a sulfolane.

The two alkyl groups in the dialkylsulfone preferably have 1 to 6 carbon atoms, more preferably have 1 to 3 carbon atoms, and yet more preferably have 1 or 2 carbon atoms (methyl group or ethyl group). The two alkyl groups may be identical to or different from each other. The two alkyl groups may be bonded to form a ring, and examples thereof include a sulfolane. The sulfolane means a substituted or unsubstituted sulfolane, and examples of the substituent include an alkyl group having 1 to 6 carbon atoms. The substituent is preferably an alkyl group having 1 to 4 carbon atoms. The substituent may be present at any carbon atom, and the number thereof is not limited. Examples of the sulfolane include sulfolane and tetramethylsulfolane.

With regard to the dialkyl sulfoxide, the two alkyl groups preferably have 1 to 6 carbon atoms, more preferably have 1 to 3 carbon atoms, and yet more preferably have 1 or 2 carbon atoms (methyl group or ethyl group). The two alkyl groups may be identical to or different from each other.

With regard to the alkylene carbonate, the alkylene group preferably has 2 to 6 carbon atoms, and more preferably 2 to 4 carbon atoms, specific examples thereof including an ethylene group, a propylene group, and a butylene group.

The number of carbon atoms of the alkyrolactone is preferably 3 to 6, and more preferably 4 to 6, and from the viewpoint of ready availability the number of carbon atoms is yet more preferably 4 or 6 (butyrolactone or caprolactone).

From the viewpoint of a relatively low boiling point, good drying properties, high safety, and ease of handling, the aprotic organic solvent (a) is preferably at least one aprotic organic solvent selected from the group consisting of a dialkyl sulfoxide, an alkylene carbonate, and an alkyrolactone, more preferably at least one aprotic organic solvent selected from the group consisting of dimethyl sulfoxide, ethylene carbonate, propylene carbonate, and γ-butyrolactone, yet more preferably at least one aprotic organic solvent selected from dimethyl sulfoxide, ethylene carbonate, and γ-butyrolactone, and most preferably γ-butyrolactone.

In the present invention, it is possible to use in combination another aprotic organic solvent that contains an oxygen atom and/or a sulfur atom in the chemical structure and does not contain a nitrogen atom in the chemical structure.

Examples of this aprotic organic solvent include ethers such as tetrahydrofuran, dimethyl ether, diethyl ether, ethyl vinyl ether, and ethylene glycol dimethyl ether, but they are not desirable since the boiling point is low, the volatility is high, the odor is strong, the flash point is low, and they are difficult to handle due to peroxide being easily generated during storage, which brings the danger of explosion. Furthermore, they easily penetrate an interface between a substrate and a conductive polymer, thus causing the possibility of degradation of adhesion. Therefore, the content of an ether in the stripping agent of the present invention is preferably no greater than 30 wt % relative to the entire stripping agent, more preferably no greater than 10 wt %, yet more preferably no greater than 3 wt %, and most preferably none.

(b) Organic Solvent that has Nitrogen Atom in Chemical Structure and is One Other than Primary Amine Compound, Secondary Amine Compound, and Organic Quaternary ammonium salt

The primary amine compound here means a compound having one hydrogen atom of ammonia (NH₃) substituted by a hydrocarbon residue, and the secondary amine compound is a compound having two hydrogen atoms of ammonia (NH₃) substituted by hydrocarbon residues. The quaternary ammonium salt is an ionic compound having all four of the hydrogen atoms bonded to the nitrogen atom of an ammonium salt (NH₄X) substituted by hydrocarbon residues.

The organic solvent (b) of the present invention is preferably a tertiary amine compound or an amide compound. In the present invention, the amide compound means one having the partial structure —C═O—NR^{a}—, and includes a urea compound. R^{a} denotes a hydrogen atom or a monovalent substituent.

Among them, the organic solvent (b) is preferably an amide compound.

Examples of the organic solvent (b) include N-alkylpyrrolidones and N-alkenylpyrrolidones such as N-methyl-2-pyrrolidone and N-vinyl-2-pyrrolidone, dialkylcarboamides such as N,N-dimethylformamide, N,N-dimethylacetamide, and N,N-diethylacetamide, 1,3-dimethyl-2-imidazolidinone, tetramethylurea, hexamethylphosphoric acid triamide, and triethanolamine.

The alkyl group of the alkylpyrrolidone preferably has 1 to 6 carbon atoms, more preferably has 1 to 4 carbon atoms, and yet more preferably has 1 to 2 carbon atoms (methyl group or ethyl group). The alkenyl group of the alkenylpyrrolidone preferably has 2 to 6 carbon atoms, more preferably has 2 to 4 carbon atoms, and yet more preferably has a vinyl group or an allyl group.

The dialkylcarboamide is preferably represented by Formula (I) below.

R¹—(C═O)—NR²R³ (1)

In Formula (I) above, R¹ denotes a hydrogen atom, an alkyl group, an alkenyl group or an alkynyl group having 1 to 6 carbon atoms, or an aryl group having 6 to 10 carbon atoms. R¹ is preferably a hydrogen atom or an alkyl group having 1 to 6 carbon atoms, more preferably a hydrogen atom or a alkyl group having 1 to 3 carbon atoms, and yet more preferably a hydrogen atom or a methyl group.

In Formula (I) above, R² and R³ independently denote an alkyl group having 1 to 6 carbon atoms, preferably 1 to 4 carbon atoms, and more preferably a methyl group or an ethyl group.

From the viewpoint of ease of handling and safety, the organic solvent (b) is preferably at least one organic solvent selected from the group consisting of an N-alkylpyrrolidone and a dialkylcarboamide, and more preferably at least one organic solvent selected from the group consisting of N-methylpyrrolidone, dimethylformamide, and dimethylacetamide. These organic solvents (b) may be used on their own or in a combination of two or more types.

Since, if the organic solvent (b) is a primary amine compound, a secondary amine compound, and/or an organic quaternary ammonium salt, the surface resistivity value of the conductive polymer is increased and the conductivity is degraded, the organic solvent (b) is an organic solvent other than a primary amine compound, a secondary amine compound, and an organic quaternary ammonium salt. As compounds that are particularly undesirable, monoethanolamine and tetramethylammonium hydroxide can be cited.

It is preferable for the stripping agent not to contain any primary amine compound, secondary amine compound, or organic quaternary ammonium salt at all; the content of the primary amine compound, the secondary amine compound, and the organic quaternary ammonium salt is preferably no greater than 5 wt % of the total stripping agent, more preferably no greater than 3 wt %, and yet more preferably none.

In the present invention, the aprotic organic solvent (a) or the organic solvent (b) may be used on its own, or the aprotic organic solvent (a) and the organic solvent (b) may be used in combination.

A mixture of the aprotic organic solvent (a) and the organic solvent (b) is preferable since the stripping properties for a resist film from a conductive polymer are good and the surface resistivity of the conductive polymer is not increased, that is, the conductivity is not degraded, and the adhesion between the substrate and the conductive polymer is not impaired.

The ratio of the aprotic organic solvent (a) to the organic solvent (b) is preferably (a)/(b)=99/1 to 10/90 (ratio by weight), and more preferably (a)/(b)=70/30 to 20/80 (ratio by weight).

The stripping agent of the present invention may contain another compound in addition to the aprotic organic solvent (a) and the organic solvent (b) in a range that does not degrade the stripping properties. Examples of such a compound include alcohols such as methanol, ethanol, ethylene glycol, and glycerol, alkylene glycols such as polyethylene glycol, polypropylene glycol, and polytetramethylene glycol, glycol ethers such as ethylene glycol monomethyl ether, ethylene glycol monoethyl ether, and ethylene glycol monobutyl ether, and water.

The component other than the aprotic organic solvent (a) and/or the organic solvent (b) is preferably at least 0 wt % but no greater than 50 wt % as a total relative to the total weight of the stripping agent (in the present invention ‘at least 0 wt % but no greater than 50 wt %’ is also expressed as ‘0 to 50 wt %’, or, ‘0 wt % to 50 wt %’, the same applies below), more preferably 0 to 30 wt %, yet more preferably 0 to 10 wt %, particularly preferably 0 to 5 wt %, and most preferably 0 to 3 wt %.

### Conductive Polymer

Examples of the conductive polymer used in the present invention include polyaniline, polythiophene, polypyrrole, polyphenylene, polyfluorene, polybithiophene, polyisothiophene, poly(3,4-ethylenedioxythiophene), polyisothianaphthene, polyisonaphthothiophene, polyacetylene, polydiacetylene, polyparaphenylene vinylene, polyacene, polythiazyl, polyethylene vinylene, polyparaphenylene, polydodecylthiophene, polyphenylene vinylene, polythienylene vinylene, polyphenylene sulfide, and derivatives thereof. Among them, polythiophenes (e.g. polythiophene, polybithiophene, polyisothiophene, poly(3,4-ethylenedioxythiophene), and polyisonaphthothiophene) and polyanilines (e.g. polyaniline) are preferable, polythiophenes are more preferable, and poly(3,4-ethylenedioxythiophene), which has excellent conductivity, stability in air, and thermal resistance, is most preferable.

In the present invention, a dopant may be used in combination for the purpose of enhancing the conductivity of the conductive polymer. The dopant may be an acceptor or an donor, and examples thereof include halogens such as iodine and chlorine, Lewis acids such as BF₃ and PF₅, protonic acids such as nitric acid and sulfuric acid, transition metals, alkali metals, amino acids, nucleic acids, surfactants, colorants, chloranil, tetracyanoethylene, and TCNQ, which are well known. As a dopant when a polythiophene is used, polystyrenesulfonic acid is preferably used.

As a specific conductive polymer, a polyaniline commercially available under the product name ‘Panipol’, manufactured by Panipol, is known, and is an organic solvent-solubilized polyaniline doped with a functional sulfonic acid. A polyaniline commercially available under the product name ‘Ormecon’, manufactured by Ormecon, is a solvent-dispersed polyaniline employing an organic acid as a dopant.

Other examples include poly(3,4-ethylenedioxythiophene), which is commercially available under the product name ‘BAYTRON’ (registered trademark), manufactured by H C Starck, or under the product name ‘CurrentFine’, manufactured by Teijin DuPont Films Japan Ltd. ‘CurrentFine’ uses polystyrenesulfonic acid as a dopant.

In addition, a polypyrrole commercially available under the product name ‘ST poly’ from Achilles Corporation, a sulfonated polyaniline commercially available under the product name ‘PETMAX’ from Toyobo Co., Ltd., and a polyaniline commercially available under the product name ‘SCS-NEO’ from Maruai Inc. may also be used in the present invention.

Conductive polymers described in Chemistry 6 ‘Organic Conductive Polymers’, 2001, of a patent licensing support chart as an enterprise for encouraging patent licensing may also be used in the present invention.

A preferred conductive polymer is poly(3,4-ethylenedioxythiophene) as described above, and examples thereof include those known under the product names ‘BAYTRON P’, ‘BAYTRON PH’, ‘BAYTRON PH500 ’, ‘BAYTRON P AG’, ‘BAYTRON P HCV4’, ‘BAYTRON FE’, and ‘BAYTRON F HC’ (H C Starck).

### Substrate

In the present invention, the conductive polymer is preferably provided on a substrate.

The substrate used in the present invention is not particularly limited, and it may be selected appropriately in accordance with an intended application or purpose.

Specific examples thereof include inorganic glasses such as soda-lime glass, silicate glass, barium glass, phosphate glass, borate glass, fluoride glass, and quartz glass, polyesters such as polyethylene terephthalate and polyethylene naphthalate, polyolefins such as polyethylene, polypropylene, poly(4-methylpentene), and cyclic polyolefins, and others such as polystyrene, polyimide, polyacrylate, and polymethacrylate.

### Resist

As a resist used in the present invention, a general-purpose photoresist or a dry film resist may be used.

With regard to the photoresist, there are a positive-working type in which a portion irradiated with UV is dissolved by a developer and a negative-working type in which a portion irradiated with UV becomes insoluble in a developer; the positive-working type is often a liquid resist, and for a display it is used in etching for line widths of on the order of a few μm to a few tens of μm in an LCD, etc.

With regard to the negative-working type, there are a liquid resist as well as a dry film resist, and for a display it is used in etching for line widths of on the order of a few tens of μm in a PDP (Plasma Display Panel), etc.

Either the positive-working or negative-working type of resist may be used in the present invention, and it may be selected according to the fineness of a target pattern and ease of use.

Examples of such a photoresist include, as positive-working photoresists, (1) a type comprising a photosensitizing agent and an alkali soluble resin, (2) a type comprising a photoreacting and acid-generating compound, an acid-decomposing and alkali-solubility increasing compound, and an alkali soluble resin, and (3) a type comprising a photoreacting and acid-generating compound and an acid-decomposing and alkali-solubility increasing group-containing resin.

On the other hand, examples of the negative-working photoresist include (4) a type comprising a photoreacting and acid- or radical-generating compound, a crosslinking agent, and an alkali soluble resin.

The positive-working photoresist (1) above that can be used in the present invention may be produced by dissolving in an organic solvent an alkali soluble resin and a photosensitizing agent formed from a naphthoquinonediazidosulfonic acid ester and/or amide of a polyhydroxy aromatic compound.

### Alkali Soluble Resin

Examples of the alkali soluble resin include a novolac resin, an acrylic resin, a copolymer of styrene and acrylic acid, and polyvinylphenol, and among them a novolac resin or polyvinylphenol is preferable. This alkali soluble novolac resin is not particularly limited, and one commonly used as a film-forming substance in a conventional positive-working photoresist composition, for example, a condensate formed from an aromatic hydroxy compound such as phenol, cresol, or xylenol and an aldehyde such as formaldehyde in the presence of an acidic catalyst such as oxalic acid or p-toluenesulfonic acid may be used.

### Photosensitizing Agent

Examples of the photosensitizing agent include a naphthoquinonediazidosulfonic acid ester of a polyhydroxy aromatic compound and/or a naphthoquinonediazidosulfonic acid amide of a polyhydroxy aromatic compound. Examples of the naphthoquinonediazidosulfonic acid include 1,2-naphthoquinonediazido-5-sulfonic acid, 1,2-naphthoquinonediazido-5-sulfonic acid, and 1,2-naphthoquinonediazido-4-sulfonic acid.

Examples of the polyhydroxy aromatic compound include 2,3,4-trihydroxybenzophenone, 2,3,4,4′-tetrahydroxybenzophenone, 2,2′,4,4′-tetrahydroxybenzophenone, and 2,3,4,2′,4′-pentahydroxybenzophenone.

The photosensitizing agent is preferably a 1,2-naphthoquinonediazido-5-sulfonic acid ester and/or 1,2-naphthoquinonediazido-4-sulfonic acid ester of a polyhydroxy aromatic compound, and more preferably a 1,2-naphthoquinonediazido-5-sulfonic acid ester or 1,2-naphthoquinonediazido-4-sulfonic acid ester of a polyhydroxybenzophenone such as 2,3,4-trihydroxybenzophenone, 2,3,4,4′-tetrahydroxybenzophenone, 2,2′,4,4′-tetrahydroxybenzophenone, or 2,3,4,2′,4′-pentahydroxybenzophenone.

### Organic Solvent

Examples of the organic solvent include esters such as ethyl acetate, butyl acetate, ethyl propionate, methyl lactate, and ethyl lactate; glycol ether acetates such as ethylene glycol monomethyl ether acetate, ethylene glycol monoethyl ether acetate, propylene glycol monomethyl ether acetate, propylene glycol monoethyl ether acetate, methyl β-methoxyisobutyrate, and ethyl β-methoxyisobutyrate; aromatic hydrocarbons such as toluene and xylene; ketones such as methyl ethyl ketone, cyclohexanone, and 2-heptanone; carbonic acid esters such as dimethyl carbonate and ethyl carbonate; and dibasic acid diesters such as diethyl oxalate. These solvents may be used on their own or in a combination of two or more types.

With regard to the mixing proportions of the alkali soluble resin and the photosensitizing agent, relative to 100 parts by weight of the alkali soluble resin, the photosensitizing agent is usually 5 to 100 parts by weight, and preferably 10 to 80 parts by weight.

The amount of solvent used is not particularly limited, and it is preferably used so that the total amount of alkali soluble resin and photosensitizing agent is usually in a concentration range of 3 to 50 wt %.

When the positive-working photoresist of (1) above is used, the developer is desirably an aqueous alkali developer. Examples of the aqueous alkali developer include an aqueous solution of an organic alkali such as tetramethylammonium hydroxide (TMAH) or an alkali metal salt such as sodium hydroxide, potassium hydroxide, sodium carbonate, potassium carbonate, sodium metasilicate, potassium metasilicate, disodium hydrogen phosphate, or trisodium phosphate. The concentration of the alkali metal salt is preferably 0.05 to 20 wt %, and more preferably 0.1 to 10 wt %. The developer dissolves an exposed part of a positive-working photoresist and comes into direct contact with a conductive polymer. Although the conductive polymer that is in contact with the developer is adversely affected in terms of conductivity, since the portion that has come into contact with the developer is later dissolved by an etching liquid, the surface resistivity of the conductive polymer that remains after etching is not adversely affected. The developer may as necessary contain an anionic surfactant, an amphoteric surfactant, and an organic solvent. The organic solvent is preferably a water-miscible organic solvent, and examples thereof include propylene glycol, ethylene glycol monophenyl ether, benzyl alcohol, and n-propyl alcohol.

### (2) Method for Stripping Resist Film

In the present invention, a method for stripping a resist film on/above a conductive polymer (resist film stripping method) is not particularly limited as long as the stripping agent of the present invention is used, but it preferably comprises (A) a step of preparing a substrate having, in order on/above the substrate, a conductive polymer and a patterned resist film, and (B) a stripping step of stripping the resist film on/above the conductive polymer on the substrate by means of a stripping agent, and uses as the stripping agent the stripping agent of the present invention. In the present invention, in addition to step (A) and step (B) above, it is preferable for the method to further comprise (C) a washing step of washing with a washing liquid after the stripping step (B) above.

Each of the steps is explained in detail below.

(A) Step of Preparing Substrate Having, in Order on/Above Substrate, Conductive Polymer and Patterned Resist Film

The step of preparing a substrate having, in order on/above the substrate, a conductive polymer and a patterned resist film preferably comprises a step of forming a conductive polymer film on a substrate, a step of forming a resist film on/above the conductive polymer film, and a step of patternwise exposing the resist film using UV and developing by means of a developer, and more preferably comprises these steps in that order.

The step of forming a conductive polymer film on a substrate involves coating the substrate with a solution of the conductive polymer and drying so as to form a thin film of the conductive polymer.

A dopant may be added by a known method. Either a method in which a dopant is introduced after a conductive polymer film is formed in advance or a method in which a dopant is inserted when preparing a conductive polymer film may be used.

The thin film of the conductive polymer is preferably at least 1 nm but no greater than 10 μm, more preferably at least 5 nm but no greater than 1,000 nm, yet more preferably at least 10 nm but no greater than 500 nm, and particularly preferably at least 10 nm but no greater than 300 nm.

The step of forming a resist film on/above the conductive polymer film so formed preferably involves coating the conductive polymer film with a resist solution and baking to thus form a resist film.

Subsequently, it preferably comprises a step of patternwise exposing the resist film using UV and developing by means of a developer. This resist film is preferably exposed via a mask pattern, thus forming a pattern on the resist film.

Subsequently, the conductive polymer is subjected to etching using the patterned resist film as a kind of mask, thus forming a conductive polymer pattern. It may be further subjected to a post-bake treatment.

Examples of an exposure light source for the resist film include an Ar laser, a semiconductor laser, a He—Ne laser, a YAG laser, and a carbon dioxide laser.

This enables a substrate to be obtained having, in order on/above the substrate, a conductive polymer and a patterned resist film.

(B) Step of Stripping Resist Film on/Above Conductive Polymer on Substrate by Stripping Agent (Stripping Step)

Finally, the resist film on/above the conductive polymer is stripped by the stripping agent of the present invention, thus giving a conductive polymer pattern.

In the stripping step, it is necessary for the substrate after the conductive polymer is subjected to patterning (hereinafter, called a test substrate) to make contact with the stripping agent. Examples of such a stripping step include a method in which a test substrate is placed in a container charged with a stripping agent and a method in which a stripping agent is sprayed on a test substrate.

In the method in which a test substrate is placed in a container, it is preferable to use the stripping agent so that a resist layer on/above the test substrate is completely immersed.

It is necessary to contact the test substrate with the stripping agent at least until the resist film is completely stripped from the conductive polymer film, it is economical in terms of the size of equipment, etc. to carry this out within 5 min at the longest, and an appropriate selection is made from preferably no longer than 3 min, yet more preferably no longer than 2 min, and particularly preferably between 1 sec and 1 min.

Since the treatment time may be shortened by also stirring the stripping agent, other than the above-mentioned spraying, a method involving immersion-shaking, liquid circulation, ultrasonic waves, etc. may be used.

In the stripping step, it is preferable to control the temperature of the stripping agent. In order to shorten the stripping time and prevent stripping residue, the stripping temperature is preferably at least 5° C., and in order to prevent degradation of the conductivity of the conductive polymer after stripping, that is, prevent an increase in the surface resistivity, the stripping temperature is preferably no greater than 60° C. The temperature of the stripping agent is preferably at least 5° C. but no greater than 50° C., more preferably at least 10° C. but no greater than 40° C., and yet more preferably at least 10° C. but no greater than 30° C.

After the stripping treatment is completed, the test substrate is pulled out, as necessary washed with distilled water or an organic solvent, and dried.

(C) Step of Washing with Washing Liquid (Washing Step)

It is preferable for there to be a washing step, after the stripping step is completed, of pulling out a test substrate and washing with a washing liquid such as water or an organic solvent.

The washing liquid used for washing is preferably water, a lower alcohol, or a mixture thereof. In the present invention, the lower alcohol is an alcohol having an optionally branched alkyl group having 1 to 4 carbon atoms, and is specifically methanol, ethanol, n-propanol, isopropanol, n-butanol, isobutanol, or tent-butanol. These lower alcohols may be mixed and used, and another alcohol having a relatively low boiling point, such as for example n-hexanol or cyclohexanol, may be mixed in a range that does not degrade the washing properties. A preferred washing liquid is ion-exchanged water, methanol, and/or ethanol, or a mixture thereof.

The time for the washing step in the present invention is preferably 30 sec to 5 min. When the time for the washing step is at least 30 sec, sufficient washing properties can be obtained, and when it is no greater than 5 min, the conductive polymer does not come off the substrate. It is preferable to set the time for the washing step in the above-mentioned range since the yield of substrate having conductive polymer is good.

In the washing step above, it is preferable to control the temperature of the washing liquid. In order to shorten the washing time and prevent washing residue, the washing temperature is preferably at least 5° C., and in order to prevent degradation of conductivity of the conductive polymer after washing, that is, prevent increase in the surface resistivity, the washing temperature is preferably no greater than 60° C. The temperature of the washing liquid is preferably at least 5° C. but no greater than 50° C., more preferably at least 10° C. but no greater than 40° C., and yet more preferably at least 10° C. but no greater than 30° C.

In the present invention, it is preferable for at least one of the stripping step and the washing step to be carried out at a temperature of 5° C. to 60° C., and it is more preferable for both the stripping step and the washing step to be carried out at a temperature of 5° C. to 60° C.

Furthermore, in the present invention, after the washing step it is preferable to carry out a drying step. With regard to the drying step, a known method may be appropriately selected.

The method for stripping a resist film of the present invention is not limited to the above-mentioned case in which a resist film formed directly on a conductive polymer is stripped. It may be applied to a case in which another film is formed on a conductive polymer, a resist is formed thereon, and stripping is carried out after patterning, or a case in which another film is formed on a substrate equipped with a patterned conductive polymer, a resist is further formed thereon, and stripping is carried out after patterning.

A detailed explanation is given below by reference to drawings. In the drawings below, the same reference numerals denote the same objects.

FIG. 1 is a process drawing showing a method for stripping a resist film formed directly on a conductive polymer.

In FIG. 1 (a), a conductive polymer 10 is formed on a substrate 20. Subsequently, a resist film 30 is formed on the conductive polymer 10 (FIG. 1 (b)). The resist film 30 is exposed via a mask pattern 40 (FIG. 1 (c)), and developed patternwise (FIG. 1 (d)). In FIG. 1, a positive-working resist is used as the resist film 30, and an exposed portion becomes soluble. The light source used for exposure is not particularly limited, and UV may be suitably used.

Subsequently, the conductive polymer 10 is etched (FIG. 1 (e)) and, furthermore, the resist film 30 on the conductive polymer 10 is stripped (FIG. 1 (f)). The stripping agent and the stripping method of the present invention may be used suitably as a stripping agent for the resist film 30 on the conductive polymer 10 shown in FIG. 1 (f) above and as a stripping method for the resist film.

FIG. 2 is a process drawing showing a method for stripping a resist film formed on a conductive polymer via another film.

In FIG. 2 (a), a conductive polymer 10 and another film 50 are formed in order on a substrate 20. Subsequently, a resist film 30 is formed on the other film 50 (FIG. 2 (b)), and in the same manner as for FIG. 1 (c) the resist film 30 is exposed via a mask pattern 40 (FIG. 2 (c)). The resist film 30 is developed patternwise (FIG. 2 (d)), and subsequently the other film 50 is etched (FIG. 2 (e)). Finally, the resist film 30 formed on the conductive polymer 10 via the other film 50 is stripped, and in this stage since the stripping agent comes into contact with the conductive polymer 10, if the stripping agent of the present invention is used, it is possible to prevent the conductivity of the conductive polymer 10 from being degraded and the surface resistivity from increasing (FIG. 2 (f)).

The stripping agent and the stripping method of the present invention may also be used as a stripping agent and a method for stripping a resist film for the resist film 30 provided on the conductive polymer 10 via the other film 50 as shown in FIG. 2 (f).

The other film here is not particularly limited, and examples thereof include wiring metal (aluminum, copper, silver, molybdenum, titanium, tantalum, chromium) for an LCD or an organic EL and an external light reflecting material (silver, etc.) used in a reflection type LCD.

### EXAMPLES

The present invention is explained below by reference to Examples, but the present invention is not limited to these Examples.

### Example 1-1

As a substrate a polyethylene terephthalate (PET) sheet was selected, and a thin film with a thickness of about 500 nm was formed on the surface thereof using BAYTRON F E (product name, containing poly(3,4-ethylenedioxythiophene), H C Starck) as a conductive polymer.

Subsequently, as a positive-working photoresist, TFR-H resist containing a naphthoquinonediazido compound and a novolac resin (Tokyo Ohka Kogyo Co., Ltd.) was applied using a spin coater, prebaking was carried out at 110° C. for 15 min, and a 2 μm thick resist layer was formed.

This resist layer was exposed at 50 mJ/cm² via a mask pattern using exposure equipment (Nikon Corporation), developed with a 2 wt % tetramethylammonium hydroxide (TMAH) aqueous solution, washed with water, and then dried to give a resist pattern.

The conductive polymer was subjected to etching using the patterned resist layer as a mask using an etching liquid mixture of 10 wt % ceric ammonium nitrate and 10 wt % nitric acid at 30° C. for 1 min, and washing with water, thus forming a conductive polymer pattern.

Finally, the resist layer on the conductive polymer was stripped by immersion using as a stripping agent dimethyl sulfoxide (hereinafter, called DMSO) at 60° C. for 2 min, thus giving test substrate A having a patterned conductive polymer.

Test substrate A was subjected to the tests below.

### Stripping Properties

A test substrate after drying was examined visually and by a 300× optical microscope, and the presence/absence of resist film that could not be stripped remaining on the conductive polymer was checked.

### Adhesion

After lines and spaces with a line width of 100 μm were cut in the resist layer, the conductive polymer film was etched, the resist layer was subsequently stripped by the stripping agent, and conductive polymer film lines of the test substrate were examined using a 100× optical microscope to check for abnormalities in the lines.

### Surface Resistivity Test

A 5 cm×5 cm square portion was cut out from the test substrate, and surface resistivity was measured using a surface resistivity meter (Loresta GP (product name), Dia Instruments Co., Ltd.) and used as a criterion for decrease in conductivity.

From the results, there were no abnormalities in the lines of conductive polymer film before coating with the resist (initial stage) and the surface resistivity was 483 Ω/square; there was hardly any resist residue on test substrate A after stripping (area of portion remaining was 1% to less than 5%), there were no abnormalities in the lines, and the surface resistivity was 604 Ω/square.

### Examples 1-2 to 1-12

Tests were carried out by the same methods as in Example 1-1 except that the stripping agent was changed to those shown in Table 1. The results are given in Table 1.

TABLE 1

| | | Evaluation | | |
|---|---|---|---|---|
| | | Stripping | | Surface resistivity |
| | Stripping agent | properties¹⁾ | Adhesion²⁾ | value (Ω/square) |
| Example 1-2 | γ-Butyrolactone | Good | Good | 588 |
| Example 1-3 | N-Methylpyrrolidone (NMP) | Excellent | Good | 688 |
| Example 1-4 | Ethylene carbonate (EC) | Good | Good | 524 |
| Example 1-5 | Dimethylformamide (DMF) | Excellent | Good | 620 |
| Example 1-6 | Dimethylacetamide (DMA) | Excellent | Good | 625 |
| Example 1-7 | DMSO/DMA = 3/7 | Excellent | Good | 491 |
| | (ratio by weight) | | | |
| Example 1-8 | DMSO/DMF = 5/5 | Excellent | Good | 503 |
| | (ratio by weight) | | | |
| Example 1-9 | DMSO/DMA =15/85 | Excellent | Good | 613 |
| | (ratio by weight) | | | |
| Example 1-10 | EC/DMF = 9/1 | Good | Good | 587 |
| | (ratio by weight) | | | |
| Example 1-11 | γ-Butyrolactone/NMP = 5/5 | Excellent | Good | 604 |
| | (ratio by weight) | | | |
| Example 1-12 | Triethanolamine | Good | Good | 620 |

¹⁾Stripping properties
Excellent: no resist residue (less than 1%)
Good: resist residue in an area of 1% to less than 5%
Fair: resist residue in an area of 5% or greater
Poor: not stripped
²⁾Adhesion
Good: no abnormalities in 100 μm line
Fair: line moved or partially stripped
Poor: line stripped and lost

### Comparative Examples 1-1 to 1-3

Tests were carried out by the same methods as in Example 1-1 except that the stripping agent was changed to ones containing a primary amine and an organic quaternary ammonium salt. The results are given in Table 2.

TABLE 2

| | | Evaluation | | |
|---|---|---|---|---|
| | | Stripping | | Surface resistivity |
| | Stripping agent | properties | Adhesion | value (Ω/square) |
| Comp. Ex. 1-1 | MEA/water = 5/5 | Fair | Fair | 5,740 |
| | (ratio by weight) | | | |
| Comp. Ex. 1-2 | MEA/DEGME = 7/3 | Good | Good | 6,020 |
| | (ratio by weight) | | | |
| Comp. Ex. 1-3 | TMAH/water = 2/8 | Good | Poor | 8,810 |
| | (ratio by weight) | | | |

MEA: 2-aminoethanol
DEGME: diethylene glycol monomethyl ether (2-(2-methoxyethoxy)ethanol)
TMAH: tetramethylammonium hydroxide

### Example 2-1

As a substrate a polyethylene terephthalate (PET) sheet was selected, and a thin film with a thickness of about 500 nm was formed on the surface thereof using product name ‘BAYTRON PH500’ (product name, containing poly(3,4-ethylenedioxythiophene), H C Starck) as a conductive polymer, and this was used as a test substrate.

Subsequently, as a positive-working photoresist, product name ‘TPR-43’, which is a resist containing a naphthoquinonediazido compound and a novolac resin, (Toagosei Co., Ltd.) was applied using a spin coater, prebaking was carried out at 90° C. for 15 min, and a 2 μm thick resist layer was formed.

This resist layer was exposed at 300 mJ/cm² via a mask pattern using exposure equipment (Nikon Corporation), developed with a 0.5 wt % potassium hydroxide (KOH) aqueous solution, washed with water, and then dried to give a resist pattern.

The conductive polymer was subjected to etching using the patterned resist layer as a mask using an etching liquid mixture of 10 wt % ceric ammonium nitrate and 10 wt % nitric acid at 30° C. for 1 min, and washing with water, thus forming a conductive polymer pattern.

Finally, the resist layer on the conductive polymer was stripped by immersion while stirring with a stirrer blade at 400 rotation/min using as a stripping agent γ-butyrolactone at 10° C. for 1 min. Subsequently, it was washed by immersion while stirring with a stirrer blade at 400 rotation/min using as a washing liquid ion exchanged water at 10° C. for 1 min.

This gave test substrate B having a patterned conductive polymer.

Test substrate B was subjected to the tests below.

### Stripping Properties

A test substrate after drying was examined by a 300× optical microscope, and the presence/absence of resist film that could not be stripped remaining on the conductive polymer was checked.

### Adhesion

After lines and spaces with a line width of 100 μm were cut in the resist layer, the conductive polymer film was etched, the resist layer was subsequently stripped by the stripping agent, and conductive polymer film lines of the test substrate were examined using a 300× optical microscope to check for abnormalities in the lines.

### Surface Resistivity Test

A 5 cm×5 cm square portion was cut out from the test substrate, and surface resistivity was measured using a surface resistivity meter (Loresta GP (product name), Dia Instruments Co., Ltd.) and used as a criterion for decrease in conductivity.

From the results, there were no abnormalities in the lines of conductive polymer film before coating with the resist (initial stage) and the surface resistivity was 295 Ω/square; there was no resist residue on test substrate B after stripping, there were no abnormalities in the lines, the surface resistivity was 343 Ω/square, and the percentage increase in surface resistivity was 16%, which was no greater than a target of 50%.

### Examples 2-2 to 2-7

Tests were carried out by the same methods as in Example 2-1 except that the treatment temperatures of the stripping agent and the washing liquid were changed to those shown in Table 3. The results are given in Table 3.

TABLE 3

| | | | Stripping | | Washing | Conductivity: surface resistivity value | | | | |
|---|---|---|---|---|---|---|---|---|---|---|
| | Conductive | Stripping | liquid | Washing | liquid | Before | After | Percentage | Stripping | |
| | polymer | liquid | temp. | liquid | temp. | treatment | treatment | increase | properties | Adhesion |
| Example | BAYTRON | γ-Butyrolactone | 10° C. | Ion | 10° C. | 295 | 343 | 16% | Excellent | Excellent |
| 2-1 | PH500 | | | exchanged | | | | | | |
| | | | | water | | | | | | |
| Example | BAYTRON | γ-Butyrolactone | 40° C. | Ion | 40° C. | 264 | 316 | 20% | Excellent | Excellent |
| 2-2 | PH500 | | | exchanged | | | | | | |
| | | | | water | | | | | | |
| Example | BAYTRON | γ-Butyrolactone | 50° C. | Ion | 50° C. | 264 | 322 | 22% | Excellent | Excellent |
| 2-3 | PH500 | | | exchanged | | | | | | |
| | | | | water | | | | | | |
| Example | BAYTRON | γ-Butyrolactone | 60° C. | Ion | 60° C. | 264 | 337 | 28% | Excellent | Excellent |
| 2-4 | PH500 | | | exchanged | | | | | | |
| | | | | water | | | | | | |
| Example | BAYTRON | γ-Butyrolactone | 10° C. | Ion | 70° C. | 295 | 402 | 36% | Excellent | Excellent |
| 2-5 | PH500 | | | exchanged | | | | | | |
| | | | | water | | | | | | |
| Example | BAYTRON | γ-Butyrolactone | 70° C. | Ion | 10° C. | 288 | 395 | 37% | Excellent | Excellent |
| 2-6 | PH500 | | | exchanged | | | | | | |
| | | | | water | | | | | | |
| Example | BAYTRON | γ-Butyrolactone | 70° C. | Ion | 70° C. | 264 | 415 | 57% | Excellent | Excellent |
| 2-7 | PH500 | | | exchanged | | | | | | |
| | | | | water | | | | | | |

### Examples 2-8 to 2-16

Tests were carried out by the same methods as in Example 2-1 except that the conductive polymer and the stripping agent were changed to those shown in Table 4. The results are given in Table 4.

### Comparative Example 2-1

Tests were carried out by the same methods as in Example 2-1 except that the stripping agent was changed to that shown in Table 4. The results are given in Table 4.

TABLE 4

| | | | Stripping | | Washing | Conductivity: surface resistivity value | | | | |
|---|---|---|---|---|---|---|---|---|---|---|
| | Conductive | Stripping | liquid | Washing | liquid | Before | After | Percentage | Stripping | |
| | polymer | liquid | temp. | liquid | temp. | treatment | treatment | increase | properties | Adhesion |
| Example | BAYTRON | N-Methylpyrrolidone | 10° C. | Ion | 10° C. | 288 | 345 | 20% | Excellent | Excellent |
| 2-8 | PH500 | | | exchanged | | | | | | |
| | | | | water | | | | | | |
| Example | BAYTRON | N-Methylpyrrolidone | 60° C. | Ion | 60° C. | 205 | 270 | 31% | Excellent | Excellent |
| 2-9 | FE | | | exchanged | | | | | | |
| | | | | water | | | | | | |
| Example | BAYTRON | Dimethyl sulfoxide | 60° C. | Ion | 60° C. | 205 | 266 | 30% | Excellent | Excellent |
| 2-10 | FE | | | exchanged | | | | | | |
| | | | | water | | | | | | |
| Example | BAYTRON | Dimethylacetamide | 60° C. | Ion | 60° C. | 205 | 270 | 31% | Excellent | Excellent |
| 2-11 | FE | | | exchanged | | | | | | |
| | | | | water | | | | | | |
| Example | BAYTRON | Dimethylformamide | 60° C. | Ion | 60° C. | 205 | 275 | 34% | Excellent | Excellent |
| 2-12 | FE | | | exchanged | | | | | | |
| | | | | water | | | | | | |
| Example | BAYTRON | Ethylene carbonate/ | 60° C. | Ion | 60° C. | 205 | 272 | 33% | Excellent | Excellent |
| 2-13 | FE | dimethylacetamide = | | exchanged | | | | | | |
| | | 1/1 (ratio by weight) | | water | | | | | | |
| Example | BAYTRON | γ-Butyrolactone/ | 10° C. | Ion | 10° C. | 288 | 368 | 28% | Excellent | Excellent |
| 2-14 | PH500 | N-methylpyrrolidone = | | exchanged | | | | | | |
| | | 1/1 (ratio by weight) | | water | | | | | | |
| Example | BAYTRON | γ-Butyrolactone/ | 20° C. | Ion | 20° C. | 288 | 341 | 18% | Excellent | Excellent |
| 2-15 | PH500 | dimethylacetamide = | | exchanged | | | | | | |
| | | 1/1 (ratio by weight) | | water | | | | | | |
| Example | BAYTRON | γ-Butyrolactone/ | 20° C. | Ion | 20° C. | 312 | 396 | 26% | Excellent | Excellent |
| 2-16 | PH500 | dimethylformamide = | | exchanged | | | | | | |
| | | 1/1 (ratio by weight) | | water | | | | | | |
| Comp. | BAYTRON | Monoethanolamine | 10° C. | Ion | 10° C. | 277 | 1220 | 340% | Excellent | Excellent |
| Ex. 2-1 | PH500 | | | exchanged | | | | | | |
| | | | | water | | | | | | |

### Examples 2-17 to 2-20

Tests were carried out by the same methods as in Example 2-1 except that the washing liquids were changed to those shown in Table 5. The results are given in Table 5.

TABLE 5

| | | | Stripping | | Washing | Conductivity: surface resistivity value | | | | |
|---|---|---|---|---|---|---|---|---|---|---|
| | Conductive | Stripping | liquid | Washing | liquid | Before | After | Percentage | Stripping | |
| | polymer | liquid | temp. | liquid | temp. | treatment | treatment | increase | properties | Adhesion |
| Example | BAYTRON | γ-Butyrolactone | 10° C. | Methanol | 10° C. | 295 | 325 | 10% | Excellent | Excellent |
| 2-17 | PH500 | | | | | | | | | |
| Example | BAYTRON | γ-Butyrolactone | 10° C. | Methanol/ion | 10° C. | 295 | 304 | 3% | Excellent | Excellent |
| 2-18 | PH500 | | | exchanged | | | | | | |
| | | | | water = | | | | | | |
| | | | | 1/1(vol) | | | | | | |
| Example | BAYTRON | γ-Butyrolactone | 10° C. | Ethanol | 10° C. | 301 | 334 | 11% | Excellent | Excellent |
| 2-19 | PH500 | | | | | | | | | |
| Example | BAYTRON | γ-Butyrolactone | 10° C. | Ethanol/ion | 10° C. | 323 | 343 | 6% | Excellent | Excellent |
| 2-20 | PH500 | | | exchanged | | | | | | |
| | | | | water = | | | | | | |
| | | | | 1/1 (vol) | | | | | | |

### Examples 2-21 to 2-28

Tests were carried out by the same methods as in Example 2-1 except that the stripping agent and the stripping temperature were changed to those shown in Table 6. The results are given in Table 6.

TABLE 6

| | | | Stripping | | Washing | Conductivity: surface resistivity value | | | | |
|---|---|---|---|---|---|---|---|---|---|---|
| | Conductive | Stripping | liquid | Washing | liquid | Before | After | Percentage | Stripping | |
| | polymer | liquid | temp. | liquid | temp. | treatment | treatment | increase | properties | Adhesion |
| Example | BAYTRON | γ-Butyrolactone/ | 20° C. | Ion | 20° C. | 312 | 355 | 14% | Excellent | Excellent |
| 2-21 | PH500 | DEGEE = | | exchanged | | | | | | |
| | | 1:1 (ratio by weight) | | water | | | | | | |
| Example | BAYTRON | γ-Butyrolactone/ | 20° C. | Ion | 20° C. | 299 | 347 | 16% | Excellent | Excellent |
| 2-22 | PH500 | DEGDME = | | exchanged | | | | | | |
| | | 1:1 (ratio by weight) | | water | | | | | | |
| Example | BAYTRON | γ-Butyrolactone/ | 20° C. | Ion | 20° C. | 293 | 325 | 11% | Excellent | Excellent |
| 2-23 | PH500 | PGME = | | exchanged | | | | | | |
| | | 1/1 (ratio by weight) | | water | | | | | | |
| Example | BAYTRON | NMP/DEGEE = 1:1 | 20° C. | Ion | 20° C. | 287 | 316 | 10% | Excellent | Excellent |
| 2-24 | PH500 | (ratio by weight) | | exchanged | | | | | | |
| | | | | water | | | | | | |
| Example | BAYTRON | NMP/DEGDME = 1:1 | 20° C. | Ion | 20° C. | 302 | 322 | 7% | Excellent | Excellent |
| 2-25 | PH500 | (ratio by weight) | | exchanged | | | | | | |
| | | | | water | | | | | | |
| Example | BAYTRON | NMP/PGME = 1/1 | 20° C. | Ion | 20° C. | 295 | 337 | 14% | Excellent | Excellent |
| 2-26 | PH500 | (ratio by weight) | | exchanged | | | | | | |
| | | | | water | | | | | | |
| Example | BAYTRON | NMP/PGME = 1/1 | 20° C. | Ion | 20° C. | 299 | 345 | 15% | Excellent | Excellent |
| 2-27 | PH500 | (ratio by weight) | | exchanged | | | | | | |
| | | | | water | | | | | | |
| Example | BAYTRON | NMP/DEGEE/ | 20° C. | Ion | 20° C. | 298 | 323 | 8% | Excellent | Excellent |
| 2-28 | PH500 | DEGDME/PGME = | | exchanged | | | | | | |
| | | 3/1/1/1 | | water | | | | | | |
| | | (ratio by weight) | | | | | | | | |

### NMP: N-methylpyrrolidone

DEGEE: diethylene glycol monoethyl ether (2-(2-ethoxyethoxy)ethanol)
DEGDME: diethylene glycol dimethyl ether (bis(2-methoxyethyl)ether)
PGME: propylene glycol monomethyl ether (1-methoxy-2-propanol)

### Comparative Examples 2-2 to 2-3

Tests were carried out by the same methods as in Example 2-1 except that the washing liquids were changed to those shown in Table 7. The results are given in Table 7.

TABLE 7

| | | | Stripping | | Washing | Conductivity: surface resistivity value | | | | |
|---|---|---|---|---|---|---|---|---|---|---|
| | Conductive | Stripping | liquid | Washing | liquid | Before | After | Percentage | Stripping | |
| | polymer | liquid | temp. | liquid | temp. | treatment | treatment | increase | properties | Adhesion |
| Comp. | BAYTRON | THF | 20° C. | Ion | 20° C. | 314 | 419 | 33% | Excellent | Poor |
| Ex. 2-2 | PH500 | | | exchanged | | | | | | |
| | | | | water | | | | | | |
| Comp. | BAYTRON | THF | 60° C. | — | — | — | — | — | — | — |
| Ex. 2-3 | PH500 | | | | | | | | | |

THF: tetrahydrofuran

In Comparative Example 2-3 of Table 7, the odor of the stripping agent was intense and, furthermore, since the amount thereof that volatilized was too large, the stripping agent evaporated, and the stripping treatment could not be carried out for a predetermined period of time.

### INDUSTRIAL APPLICABILITY

The stripping agent and the stripping method of the present invention not only have excellent stripping properties but also do not cause any degradation in the conductivity of a conductive polymer and do not affect the adhesion between a substrate and a conductive polymer film. Furthermore, the stripping agent of the present invention is highly safe and easy to handle.

The stripping agent and the stripping method of the present invention contribute to improvements in the productivity of electrolytic capacitors, antistatic films, polymer EL, solar cells, transparent conductive films, etc. that employ a conductive polymer.

1. A stripping agent for a resist film on/above a conductive polymer, comprising at least one organic solvent selected from the group consisting of an aprotic organic solvent (a) that is selected from the group consisting of a dialkylsulfone, a dialkyl sulfoxide, an alkylene carbonate, and an alkyrolactone and does not have a nitrogen atom and an organic solvent (b) that has a nitrogen atom in the chemical structure and is one other than a primary amine compound, a secondary amine compound, and an organic quaternary ammonium salt.

2. The stripping agent for a resist film on/above a conductive polymer according to claim 1, wherein the aprotic organic solvent (a) comprises at least one aprotic organic solvent selected from the group consisting of a dialkyl sulfoxide, an alkylene carbonate, and an alkyrolactone.

3. The stripping agent for a resist film on/above a conductive polymer according to claim 1, wherein the aprotic organic solvent (a) comprises at least one aprotic organic solvent selected from the group consisting of dimethyl sulfoxide, ethylene carbonate, propylene carbonate, and g-butyrolactone.

4. The stripping agent for a resist film on/above a conductive polymer according to claim 1, wherein it comprises the aprotic organic solvent (a) and the organic solvent (b).

5. The stripping agent for a resist film on/above a conductive polymer according to claim 4, wherein the ratio of the aprotic organic solvent (a) to the organic solvent (b) is (a)/(b)=99/1 to 10/90 (ratio by weight).

6. The stripping agent for a resist film on/above a conductive polymer according to claim 1, wherein the organic solvent (b) comprises at least one organic solvent selected from the group consisting of an N-alkylpyrrolidone and a dialkylcarboamide.

7. The stripping agent for a resist film on/above a conductive polymer according to claim 1, wherein the organic solvent (b) comprises at least one organic solvent selected from the group consisting of N-methylpyrrolidone, dimethylformamide, and dimethylacetamide.

8. The stripping agent for a resist film on/above a conductive polymer according to claim 1, wherein the conductive polymer is a polyaniline and/or a polythiophene.

9. The stripping agent for a resist film on/above a conductive polymer according to claim 1, wherein the conductive polymer is poly(3,4-ethylenedioxythiophene).

10. A method for stripping a resist film, comprising
a step of preparing a substrate having in order on/above the substrate a conductive polymer and a patterned resist film, and a stripping step of stripping the resist film on/above the conductive polymer on/above the substrate with a stripping agent, the stripping agent being the stripping agent for a resist film on/above a conductive polymer according to claim 1.

11. The method for stripping a resist film according to claim 10, wherein it further comprises a washing step of washing with a washing liquid after the stripping step.

12. The method for stripping a resist film according to claim 11, wherein the stripping step and/or the washing step are carried out at a temperature of 5° C. to 60° C.

13. The method for stripping a resist film according to claim 11, wherein the washing liquid is water, a lower alcohol, or a mixture of water and a lower alcohol.

14. The method for stripping a resist film according to claim 10, wherein the conductive polymer is a polyaniline and/or a polythiophene.

15. The method for stripping a resist according to claim 10, wherein the conductive polymer is poly(3,4-ethylenedioxythiophene).

16. The method for stripping a resist film according to claim 10, wherein the step of preparing a substrate having in order on/above the substrate a conductive polymer and a patterned resist film comprises a step of forming a conductive polymer film on/above a substrate, a step of forming a resist film on/above the conductive polymer film, and a step of patternwise exposing the resist film using UV and developing with a developer.

17. A substrate having a patterned conductive polymer, a resist being stripped by the method according to claim 10.
